(19) United States
(12) Patent Application Publication
(10) Pub. No.: US 2014/0054553 A1
(43) Pub. Date: Feb. 27, 2014

(54) ACTIVE MATRIX ORGANIC LIGHT-EMITTING DIODE PANEL PACKAGING STRUCTURE

(71) Applicant: Chihche Liu, Shenzhen (CN)

(72) Inventor: Chihche Liu, Shenzhen (CN)

(21) Appl. No.: 13/699,632

(22) PCT Filed: Sep. 13, 2012
(86) PCT No.: PCT/CN12/81314

§ 371 Date: Nov. 22, 2012

(30) Foreign Application Priority Data
Aug. 24, 2012 (CN) 201210305580.6

(51) Int. Cl. H01L 27/32

(52) U.S. Cl. CPC H01L 27/3244
USPC 257/40; 257/88

(57) ABSTRACT

The present invention provides an active matrix organic light-emitting diode (AMOLED) panel packaging structure, which includes a substrate, a pixel zone formed on the substrate, multiple loops of inorganic packaging material formed on the substrate and located outside the pixel zone, multiple loops of organic bonding material formed on the substrate and located outside the pixel zone, and a back lid covering over the inorganic packaging material and the organic bonding material. The multiple loops of inorganic packaging material include at least one loop that circumferentially and hermetically surrounds the pixel zone. The multiple loops of organic bonding material include at least one loop that circumferentially and hermetically surrounds the pixel zone. The inorganic packaging material and the organic bonding material are arranged to separate from each other. The AMOLED panel packaging structure possesses advantages of excellent packaging sealability and bondability and helps realization of size enlargement of AMOLED panel.

### BACKGROUND OF THE INVENTION

1. Field of the Invention

The present invention relates to the field of organic light-emitting diode, and in particular to an active matrix organic light-emitting diode panel packaging structure.

2. The Related Arts

OLED (Organic Light-Emitting Diode) is luminescence caused by injection and recombination of carriers when an organic semiconductor material and luminescent material is driven by an electric field. Luminescence of OLED is achieved by using an ITO transparent electrode and a metal electrode as anode and cathode of a device by which a predetermined voltage is applied to drive electrons and electron holes that are injected through the cathode and the anode into electron and hole transportation layers and migrate from the electron and hole transportation layers to a luminescent layer where the electrons and the holes meet each other to form excitons and excite luminescent molecules. The later, after radiative relaxation, gives off visible light. It provides the following advantages:

(1) Thickness can be less than 1 millimeter, which is only ⅓ of an LED screen, and the weigh is lighter.

(2) It is a solid state mechanism and has no liquid substance so that shock resistance is improved, showing characteristics of impact endurability.

(3) It has almost no view angle problem and the image can maintain not distorted even being watched at a great view angle.

(4) Reponses time is one thousandth of LCD and no blur will occur for displaying motion.

(5) It has excellent low temperature characteristics and can normally work at 40 degrees below zero, which cannot be fulfilled by an LED.

(6) The manufacture process is easy and the cost is even lower.

(7) It has higher luminescence efficiency and consumes less energy that LCD.

(8) It can be manufactured on substrates of various materials and can be made a flexible display that can be flexed.

Past researches indicated that the packaging of an active matrix organic light-emitting diode (AMOLED) is of great effect on the lifespan of the panel. Currently, most of the AMOLED panel developers adopt glass frit packaging. This greatly improves the utilization and lifespan of the AMOLED panels. However, since glass cement is rigid, although it could effectively block humidity and oxygen, yet the bonding property is poor. Thus, to achieve size enlargement for AMOLED panels, the bonding property for jointing a substrate and a back lid is a severe challenge for glass cement. A large-sized AMOLED panel packaging must feature both bonding property and the capability of blocking humidity and oxygen.

### SUMMARY OF THE INVENTION

An object of the present invention is to provide an active matrix organic light-emitting diode (AMOLED) panel packaging structure, which is excellent in both packaging sealability and bondability and facilitates the realization of size enlargement of AMOLED panel.

To achieve the object, the present invention provides an active matrix organic light-emitting diode panel packaging structure, which comprises a substrate, a pixel zone formed on the substrate, multiple loops of inorganic packaging material formed on the substrate and located outside the pixel zone, multiple loops of organic bonding material formed on the substrate and located outside the pixel zone, and a back lid covering over the inorganic packaging material and the organic bonding material. The multiple loops of inorganic packaging material include at least one loop that circumferentially and hermetically surrounds the pixel zone. The multiple loops of organic bonding material include at least one loop that circumferentially and hermetically surrounds the pixel zone. The inorganic packaging material and the organic bonding material are arranged to separate from each other.

The loop of inorganic packaging material that circumferentially and hermetically surrounds the pixel zone has a width of 300 um-2000 um.

The loop of the organic bonding material that circumferentially and hermetically surrounds the pixel zone has a width of 500 um-4000 um.

The inorganic packaging material is arranged to directly contact each other or to be spaced from each other and the organic bonding material is arranged to directly contact each other or to be spaced from each other.

The inorganic packaging material and the organic bonding material are formed outside the pixel zone in an arbitrary arrangement.

The loop of inorganic packaging material that is formed on the substrate outside the pixel zone and circumferentially and hermetically surrounds the pixel zone is of a number of one and the loop of organic bonding material that is formed on the substrate outside the pixel zone and circumferentially and hermetically surrounds the pixel zone is of a number of one.

The active matrix organic light-emitting diode panel packaging structure further comprises an additional loop of inorganic packaging material formed on the substrate outside the pixel zone and circumferentially and hermetically surrounding the pixel zone. The loop of organic bonding material is arranged between the two loops of inorganic packaging material.

The active matrix organic light-emitting diode panel packaging structure further comprises an additional organic bonding material formed on the substrate outside the pixel zone and circumferentially and intermittently surrounding the pixel zone. The loop of inorganic packaging material is arranged between the two loops of organic bonding material.

The inorganic packaging material comprises glass cement.

The organic bonding material comprises organic adhesive. The organic adhesive is epoxy resin.

The present invention also provides an active matrix organic light-emitting diode panel packaging structure, which comprises a substrate, a pixel zone formed on the substrate, multiple loops of inorganic packaging material formed on the substrate and located outside the pixel zone, multiple loops of organic bonding material formed on the substrate and located outside the pixel zone, and a back lid covering over the inorganic packaging material and the organic bonding material, the multiple loops of inorganic packaging material including at least one loop that circumferentially and hermetically surrounds the pixel zone, the multiple loops of organic bonding material including at least one loop that circumferentially and hermetically surrounds the pixel zone, the inorganic packaging material and the organic bonding material being arranged to separate from each other;

wherein the loop of inorganic packaging material that circumferentially and hermetically surrounds the pixel zone has a width of 300 um-2000 um;

wherein the loop of the organic bonding material that circumferentially and hermetically surrounds the pixel zone has a width of 500 um-4000 um;

wherein the inorganic packaging material is arranged to directly contact each other or to be spaced from each other and the organic bonding material is arranged to directly contact each other or to be spaced from each other;

wherein the inorganic packaging material and the organic bonding material are formed outside the pixel zone in an arbitrary arrangement;

wherein the loop of inorganic packaging material that is formed on the substrate outside the pixel zone and circumferentially and hermetically surrounds the pixel zone is of a number of one and the loop of organic bonding material that is formed on the substrate outside the pixel zone and circumferentially and hermetically surrounds the pixel zone is of a number of one;

further comprising an additional loop of inorganic packaging material formed on the substrate outside the pixel zone and circumferentially and hermetically surrounding the pixel zone, the loop of organic bonding material being arranged between the two loops of inorganic packaging material;

wherein the inorganic packaging material comprises glass cement; and

wherein the organic bonding material comprises organic adhesive, the organic adhesive being epoxy resin.

The efficacy of the present invention is that the present invention provides an active matrix organic light-emitting diode panel packaging structure, which comprises at least one loop of organic bonding material that circumferentially and hermetically surrounds the pixel zone so as to overcome the issue of poor bondability for large-sized panels. The separate arrangement of the organic bonding material and the inorganic packaging material helps keeping the individual performance and at the same time not mutually affect each other so that the structure possesses both advantages of excellent packaging sealability and bondability and helps the realization of size enlargement of an active matrix organic light-emitting diode.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a schematic view showing an active matrix organic light-emitting diode (AMOLED) panel packaging structure according to a first preferred embodiment of the present invention;

FIG. 2 is a schematic view showing an AMOLED panel packaging structure according to a second preferred embodiment of the present invention; and

FIG. 3 is a schematic view showing an AMOLED panel packaging structure according to a third preferred embodiment of the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

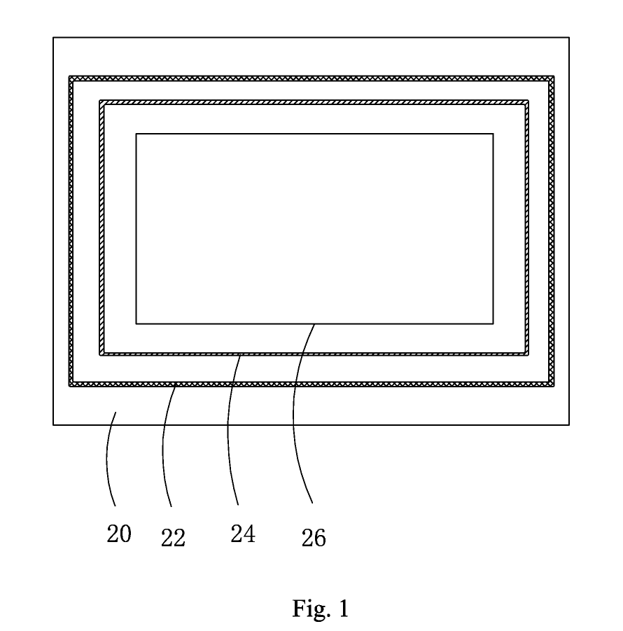

Referring to FIG. 1, the present invention provides an active matrix organic light-emitting diode (AMOLED) panel packaging structure, which comprises a substrate 20, a pixel zone 26 formed on the substrate 20, multiple loops of inorganic packaging material 24 formed on the substrate 20 and located outside the pixel zone 26, multiple loops of organic bonding material 22 formed on the substrate 20 and located outside the pixel zone 26, and a back lid (not shown) covering over the inorganic packaging material 24 and the organic bonding material 22. The multiple loops of inorganic packaging material 24 include at least one loop that circumferentially and hermetically surrounds the pixel zone 26. The multiple loops of organic bonding material 22 include at least one loop circumferentially and hermetically surround the pixel zone 26. The inorganic packaging material 24 and the organic bonding material 22 are arranged to separate from each other.

The loop of inorganic packaging material 24 that circumferentially and hermetically surrounds the pixel zone 26 has a width of 300 um-2000 um. The loop of the organic bonding material 22 that circumferentially and hermetically surrounds the pixel zone 26 has a width of 500 um-4000 um.

The inorganic packaging material 24 is arranged to directly contact each other or to be spaced from each other. The organic bonding material 22 is arranged to directly contact each other or to be spaced from each other.

The inorganic packaging material 24 and the organic bonding material 22 are formed outside the pixel zone 26 in an arbitrary arrangement. In the instant preferred embodiment, in the active matrix organic light-emitting diode panel packaging structure according to the present invention, the loop of inorganic packaging material 24 that is formed on the substrate 20 outside the pixel zone 26 and circumferentially and hermetically surrounds the pixel zone 26 is of a number of one; the loop of organic bonding material 22 that is formed on the substrate 20 outside the pixel zone 26 and circumferentially and hermetically surrounds the pixel zone 26 is of a number of one. Said loop of inorganic packaging material 24 can be arranged inside said loop of inorganic bonding material 22 or outside said loop of inorganic bonding material 22.

The inorganic packaging material 24 can be glass cement. The organic bonding material 22 can be organic adhesive. In the instant preferred embodiment, the organic adhesive is preferably epoxy resin.

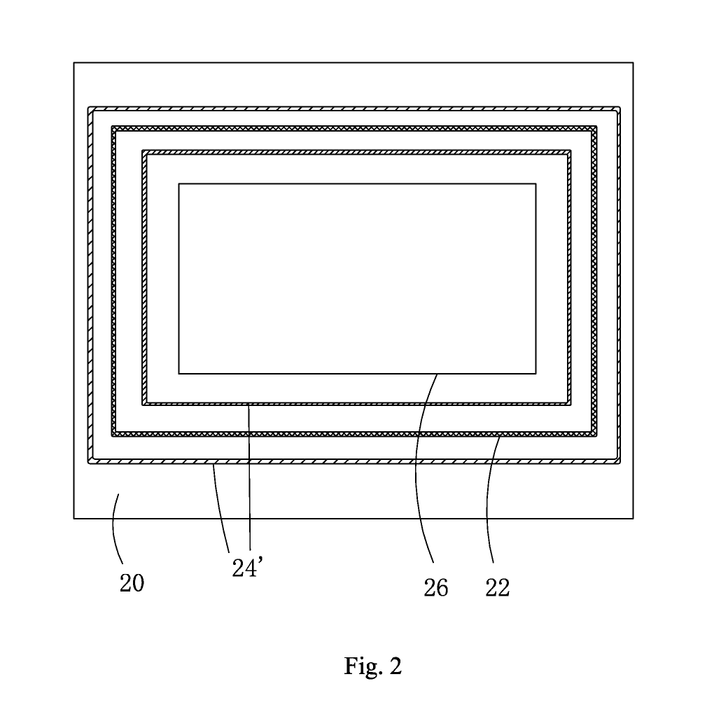

Referring to FIG. 2, an alternative second preferred embodiment is illustrated, which, on the basis of the first preferred embodiment, comprises an additional loop of inorganic packaging material 24′ that is formed on the substrate 20 outside the pixel zone 26 and circumferentially and hermetically surrounds the pixel zone 26. Said loop of organic bonding material 22 is arranged between the two loops of inorganic packaging material 24′.

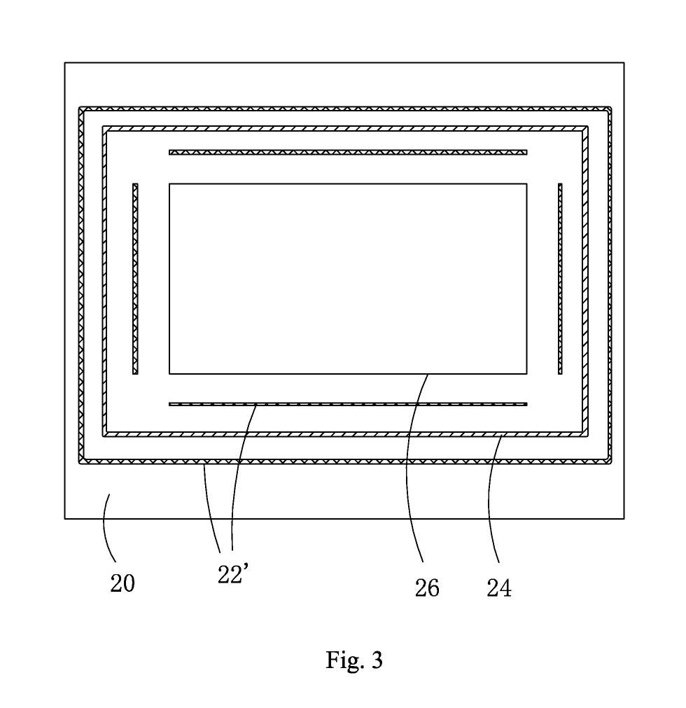

Referring to FIG. 3, an alternative third preferred embodiment is illustrated, which, on the basis of the first preferred embodiment, comprises an additional loop of organic bonding material 22′ that is formed on the substrate 20 outside the pixel zone 26 and circumferentially and non-hermetically surrounds the pixel zone 26. Said loop of inorganic packaging material 24 is arranged between the two loops of organic bonding material 22′.

In summary, the present invention provides an active matrix organic light-emitting diode panel packaging structure, which possesses both advantages of excellent packaging sealability and bondability and helps the realization of size enlargement of an active matrix organic light-emitting diode. The packaging structure comprises at least one loop of organic bonding material that circumferentially and hermetically surrounds the pixel zone. The separate arrangement of the organic bonding material and the inorganic packaging material helps keeping the individual performance and at the same time not mutually affect each other so as to overcome the issue of poor bondability for large-sized panels.

Based on the description given above, those having ordinary skills of the art may easily contemplate various changes and modifications of the technical solution and technical ideas of the present invention and all these changes and modifications are considered within the protection scope of right for the present invention.

What is claimed is:

1. An active matrix organic light-emitting diode panel packaging structure, comprising a substrate, a pixel zone formed on the substrate, multiple loops of inorganic packaging material formed on the substrate and located outside the pixel zone, multiple loops of organic bonding material formed on the substrate and located outside the pixel zone, and a back lid covering over the inorganic packaging material and the organic bonding material, the multiple loops of inorganic packaging material including at least one loop that circumferentially and hermetically surrounds the pixel zone, the multiple loops of organic bonding material including at least one loop that circumferentially and hermetically surrounds the pixel zone, the inorganic packaging material and the organic bonding material being arranged to separate from each other.

2. The active matrix organic light-emitting diode panel packaging structure as claimed in claim 1, wherein the loop of inorganic packaging material that circumferentially and hermetically surrounds the pixel zone has a width of 300 um-2000 um.

3. The active matrix organic light-emitting diode panel packaging structure as claimed in claim 1, wherein the loop of the organic bonding material that circumferentially and hermetically surrounds the pixel zone has a width of 500 um-4000 um.

4. The active matrix organic light-emitting diode panel packaging structure as claimed in claim 1, wherein the inorganic packaging material is arranged to directly contact each other or to be spaced from each other and the organic bonding material is arranged to directly contact each other or to be spaced from each other.

5. The active matrix organic light-emitting diode panel packaging structure as claimed in claim 1, wherein the inorganic packaging material and the organic bonding material are formed outside the pixel zone in an arbitrary arrangement.

6. The active matrix organic light-emitting diode panel packaging structure as claimed in claim 5, wherein the loop of inorganic packaging material that is formed on the substrate outside the pixel zone and circumferentially and hermetically surrounds the pixel zone is of a number of one and the loop of organic bonding material that is formed on the substrate outside the pixel zone and circumferentially and hermetically surrounds the pixel zone is of a number of one.

7. The active matrix organic light-emitting diode panel packaging structure as claimed in claim 6 further comprising an additional loop of inorganic packaging material formed on the substrate outside the pixel zone and circumferentially and hermetically surrounding the pixel zone, the loop of organic bonding material being arranged between the two loops of inorganic packaging material.

8. The active matrix organic light-emitting diode panel packaging structure as claimed in claim 6 further comprising an additional organic bonding material formed on the substrate outside the pixel zone and circumferentially and intermittently surrounding the pixel zone, the loop of inorganic packaging material being arranged between the two loops of organic bonding material.

9. The active matrix organic light-emitting diode panel packaging structure as claimed in claim 1, wherein the inorganic packaging material comprises glass cement.

10. The active matrix organic light-emitting diode panel packaging structure as claimed in claim 1, wherein the organic bonding material comprises organic adhesive, the organic adhesive being epoxy resin.

11. An active matrix organic light-emitting diode panel packaging structure, comprising a substrate, a pixel zone formed on the substrate, multiple loops of inorganic packaging material formed on the substrate and located outside the pixel zone, multiple loops of organic bonding material formed on the substrate and located outside the pixel zone, and a back lid covering over the inorganic packaging material and the organic bonding material, the multiple loops of inorganic packaging material including at least one loop that circumferentially and hermetically surrounds the pixel zone, the multiple loops of organic bonding material including at least one loop that circumferentially and hermetically surrounds the pixel zone, the inorganic packaging material and the organic bonding material being arranged to separate from each other;
wherein the loop of inorganic packaging material that circumferentially and hermetically surrounds the pixel zone has a width of 300 um-2000 um;
wherein the loop of the organic bonding material that circumferentially and hermetically surrounds the pixel zone has a width of 500 um-4000 um;
wherein the inorganic packaging material is arranged to directly contact each other or to be spaced from each other and the organic bonding material is arranged to directly contact each other or to be spaced from each other;
wherein the inorganic packaging material and the organic bonding material are formed outside the pixel zone in an arbitrary arrangement;
wherein the loop of inorganic packaging material that is formed on the substrate outside the pixel zone and circumferentially and hermetically surrounds the pixel zone is of a number of one and the loop of organic bonding material that is formed on the substrate outside the pixel zone and circumferentially and hermetically surrounds the pixel zone is of a number of one;
further comprising an additional loop of inorganic packaging material formed on the substrate outside the pixel zone and circumferentially and hermetically surrounding the pixel zone, the loop of organic bonding material being arranged between the two loops of inorganic packaging material;
wherein the inorganic packaging material comprises glass cement; and
wherein the organic bonding material comprises organic adhesive, the organic adhesive being epoxy resin.
